(19) United States
(12) Patent Application Publication
(10) Pub. No.: US 2005/0066259 A1
(43) Pub. Date: Mar. 24, 2005

(54) Viterbi detection apparatus and method therefor

(75) Inventors: Hyun-soo Park, Seoul (KR); Jung-hyun Lee, Seoul (KR); Jae-seong Shim, Seoul (KR); Jae-wook Lee, Osan-si (KR); Eing-seob Cho, Yongin-si (KR); Eun-jin Ryu, Suwon-si (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., Ltd., Suwon-si (KR)

(21) Appl. No.: 10/862,880

(22) Filed: Jun. 8, 2004

(30) Foreign Application Priority Data
Sep. 20, 2003 (KR) 2003-65410

(51) Int. Cl. H03M 13/03

(52) U.S. Cl. 714/795

(57) ABSTRACT

A Viterbi detection apparatus and a method therefor remove code error paths generated in optical Viterbi detection. Accordingly, paths containing 1T code based on a code condition are removed even under a condition PR (a, b) by extending a radix structure to facilitate high speed operation.

### CROSS-REFERENCE TO RELATED APPLICATIONS

This application claims the priority of Korean Patent Application No. 2003-65410, filed on Sep. 20, 2003, in the Korean Intellectual Property Office, the disclosure of which is incorporated herein in its entirety by reference.

### BACKGROUND OF THE INVENTION

1. Field of the Invention

The present invention relates to a Viterbi detection apparatus and a method therefor, and more specifically, to a Viterbi detection apparatus and a method therefore, to remove a code error path occurring in an optical disk Viterbi detection apparatus.

2. Description of the Related Art

In an optical disk system, binary data recorded on an optical disk are reproduced by illuminating laser beams on the disk and detecting reflected waves. In general, signals read out from the disk are RF (radio frequency) signals. The RF signal read out from the disk is not a digital but an analog signal due to physical and optical characteristics of the disk. Therefore, a process of conversion to a binary signal and a PLL (phase lock loop) process are necessary to convert an analog signal to a digital signal. With respect to conversion apparatuses that convert analog signals to binary signals, a Viterbi decoder is known to known to obtain least erroneous binary signals. In addition, the Viterbi decoder is known to detect the binary signal under an optimal condition suitable for channel characteristics. The Viterbi decoder is known to have better performance than a simple signal detection circuit or a run-length-correction decoder.

The present invention relates to optical disk partial response maximum likelihood (PRML) and trellis structures. Conventional optical disk PRML and trellis structures are disclosed in U.S. Pat. No. 5,781,590 by Masato Shiokawa, et al., entitled “Signal Processing Apparatus,” Korean Patent No. 238322 by Sung-han Choi, et al., entitled “Viterbi detection apparatus and method,” Korean Application No. 1998-41387 by Sung-han Choi, et al., entitled “high-speed Viterbi detection apparatus,” and Korean Application No. 2000-64521 by Sung-han Choi, et al., entitled “high-speed Viterbi detection apparatus.”

A conventional radix-2 Viterbi detection apparatus using a PR (1, 1) equalizer is used to reproduce data in an optical disk system. FIG. 1 illustrates a trellis diagram of the conventional radix-2 Viterbi detection apparatus. The Viterbi detection apparatus comprises a branch metric generation unit to generate branch metrics for an input signal, an addition comparison selection unit to add the branch metrics to state metrics to obtain new state metrics and to compare the new state metrics of paths to select retaining paths, and a path memory to store and output sequential output signals corresponding to the selected retaining paths.

In the Korean Patent Application No 2000-64521, facilitation of a high-speed operation of operational channels of a path memory and an addition comparison selection unit having a complex operational procedure of reducing a frequency of a main channel clock signal by using an auxiliary clock signal having a frequency of 1/n of the frequency of the main clock signal in an Viterbi detection apparatus is described.

However, in the aforementioned Viterbi detection apparatuses, it is impossible to detect 1T paths under an equalizer condition PR (a, b) when hardware is implemented in a radix-2 structure. In other words, paths containing 1T code may be removed only under an equalizer condition PR (a, b, c) or more. FIG. 1 illustrates a trellis diagram to illustrate the aforementioned Viterbi detection apparatuses under a code condition RLL(1, 7) and an equalizer condition PR (a, b). Referring to FIG. 1, since the equalizer condition is PR (a, b), state change levels are only three levels of +max, zero, and −max. As a result, the trellis structure has a shape of butterfly. The trellis diagram cannot represent a consecutive code arrangement. That is, since hardware needs be implemented to calculate branch metrics and state metrics with reference to a trellis diagram, it is impossible to remove unnecessary paths based on a code condition. FIG. 2 illustrates state changes in the aforementioned Viterbi detection apparatuses. As described above, since only the current and next states are represented, it is impossible to find a code arrangement containing the 1T code under the 1T code condition. As a result, the operations must be carried out on all the paths. In addition, the impossibility of finding the code arrangement containing a 1T code may lead to an erroneous Viterbi operation.

### SUMMARY OF THE INVENTION

The present invention provides a Viterbi detection apparatus to remove paths containing 1T code based on a code condition by extending a radix structure to facilitate high-speed operation.

According to an aspect of the present invention, a Viterbi detection apparatus includes a branch metric calculation unit, an addition comparison selection unit, and a path memory, wherein multiple bits are processed during a single operational clock cycle by using an auxiliary clock signal having 1/n of a frequency of a main clock signal and a path of a signal having a shorter cycle than an input code, which is not detected in the case of operating based on an existing clock signal.

According to another aspect of the present invention, a Viterbi detection apparatus includes a branch metric calculation unit, an addition comparison selection unit, and a path memory, a frequency divider to divide a frequency of a main clock signal by n (n is an natural number of 2 or more) to generate an auxiliary clock signal; a serial-to-parallel conversion unit to output branch metrics in n state units, wherein the branch metrics are calculated based on the main clock signal; and a parallel-to-serial conversion unit to convert an output data of the path memory to serial data based on the auxiliary clock signal, wherein a path of a signal which is out of accord with a code condition in the case of operating based on an existing clock signal is removed from paths selected by the addition comparison selection unit.

According to still another aspect of the present invention, a Viterbi detection apparatus comprises a branch metric calculation unit to calculate branch metrics; an addition comparison selection unit to calculate state metrics based on the branch metrics, compare the state metrics, select a path having a smallest value among the state metrics, and generate a path selection signal; and a path memory unit to output data corresponding to the path selection signal, wherein a state metric calculation is not performed on paths which are out of accord with a code condition when a structure of Viterbi decoding apparatus is extended from radix-2 to radix-4 or more structures.

The Viterbi detection apparatus may further comprise: a frequency divider to generate an auxiliary clock signal having a frequency obtained by dividing a frequency of a main clock signal by n; a serial-to-parallel conversion unit to output branch metrics in n state units, wherein the branch metrics are calculated based on the main clock signal in the branch metric calculation unit; and a parallel-to-serial conversion unit to store the path selection signal based on the auxiliary clock signal and output data corresponding to the path selection signal in parallel.

The Viterbi detection apparatus may further comprise an equalizer, wherein an output condition of the equalizer is PR (a, b).

The branch metric calculation unit may comprise: an absolute value operation unit to calculate the branch metric of each branch by performing an absolute value operation on a difference between a reference level value and an input signal; and an addition unit to calculate a path branch metric by selecting and adding the calculated branch metrics based on the corresponding states.

In the addition unit, the path metric calculation may be not performed on paths which are out of accord with a code condition among paths available to the corresponding states.

According to still another aspect of the present invention, a Viterbi detection method comprises: calculating branch metrics; calculating state metrics based on the branch metrics, comparing the state metrics, selecting a path having a smallest value among the state metrics, and generating a path selection signal; and outputting data corresponding to the path selection signal, wherein a state metric calculation is not performed on paths which are out of accord with a code condition when a structure of Viterbi decoding apparatus is extended from radix-2 to radix-4 or more structures.

Additional aspects and/or advantages of the invention will be set forth in part in the description which follows and, in part, will be obvious from the description, or may be learned by practice of the invention.

### BRIEF DESCRIPTION OF THE DRAWINGS

The above and/or other features and advantages of the present invention will become more apparent by describing in detail exemplary embodiments thereof with reference to the attached drawings in which:

FIG. 1 is a trellis diagram of a conventional Viterbi detection apparatus;

FIG. 2 illustrates a state change table of the conventional Viterbi detection apparatus of FIG. 1;

FIG. 3 is a trellis diagram of a Viterbi detection apparatus according to an embodiment of the present invention;

FIG. 4 illustrates a state change table corresponding to the trellis diagram of FIG. 3;

FIG. 5 illustrates trellis diagrams before and after 1T paths are removed;

FIG. 6 is a view illustrating a construction of the Viterbi detection apparatus according to an embodiment of the present invention;

FIG. 7 is a view illustrating a construction of a branch metric calculation unit according to the present invention;

FIG. 8 is a view illustrating an internal construction of an absolute value calculation unit;

FIGS. 9A-9B are views of an embodiment of the present invention illustrating addition, comparison, and selection operations on the state metrics for all the paths going into the states +1 and −1, respectively, wherein the paths which are out of accord with the code condition are removed; and

FIG. 10 is a view illustrating a path memory according to an embodiment of the present invention.

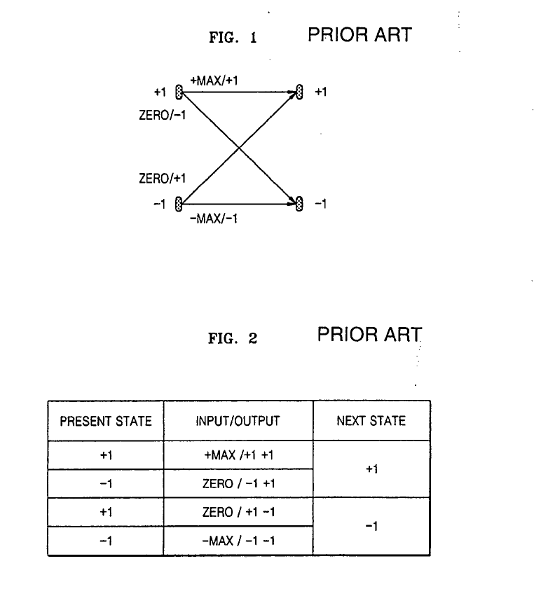

### DETAILED DESCRIPTION OF THE PREFERRED EMBODIMENTS

Reference will now be made in detail to the embodiments of the present invention, examples of which are illustrated in the accompanying drawings, wherein like reference numerals refer to the like elements throughout. The embodiments are described below to explain the present invention by referring to the figures.

The present invention and operational advantages thereof may be fully understood by referring to the accompanying drawings and explanations thereof.

Now, exemplary embodiments of the present invention will be described with reference to the accompanying drawings to explain the present invention in detail. In the drawings, the same reference numerals indicate the same elements.

FIG. 3 is a trellis diagram of a Viterbi detection apparatus according to an embodiment of the present invention. In a radix-4 trellis diagram of FIG. 3, there is an intermediate state (MID STATE) which does not exist in a conventional radix-2 trellis diagram. An operational unit in an addition comparison selection unit represents a sum of two branch metrics rather than a single branch metric. Extension of the operational unit facilitates the detection of paths including a 1T code. If a structure of a Viterbi detection apparatus is extended from radix-2 to radix-8 structures in a similar manner of FIG. 3, the operational unit is extended to a sum of three branch metrics. The operational unit may be further extended in a similar manner.

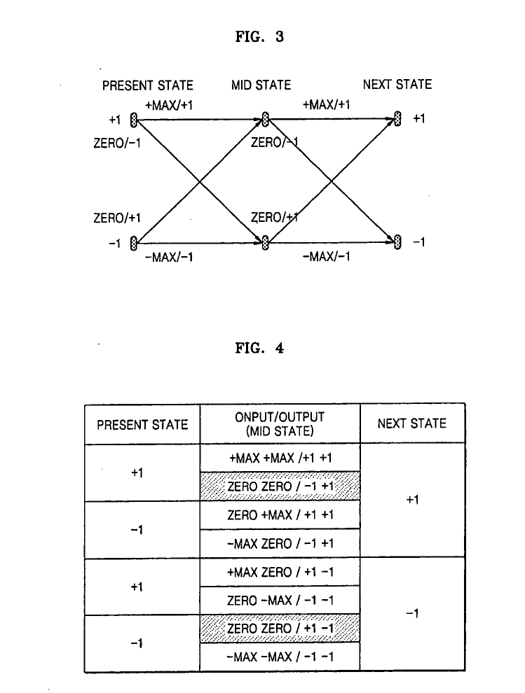

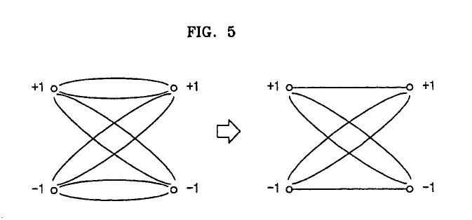

FIG. 4 illustrates a state change table corresponding to the trellis diagram of FIG. 3. Before paths having the 1T code are removed, the number of paths changing from the current state +1 to the next state +1 is two. Similarly, the numbers of paths changing from the current state −1 to the next state +1, from the current state +1 to the next state −1, and from the current state −1 to the next state −1 are also two. The change of state from +1 to +1 occurs when input signals “+max +max” or “zero zero” are received. The output signals of the Viterbi detection apparatus are “+1 +1” and “−1 +1”, respectively. Since the state metric value of the initial state is +1, the code arrangement of the output signal is “+1 +1 +1” or +1 −1 +1. The code arrangement +1 −1 +1 is not available due to the code condition, so the corresponding paths may be removed. It can be understood that paths corresponding to input signal “zero zero” in case of the state changing from −1 to −1 may be removed in a similar manner.

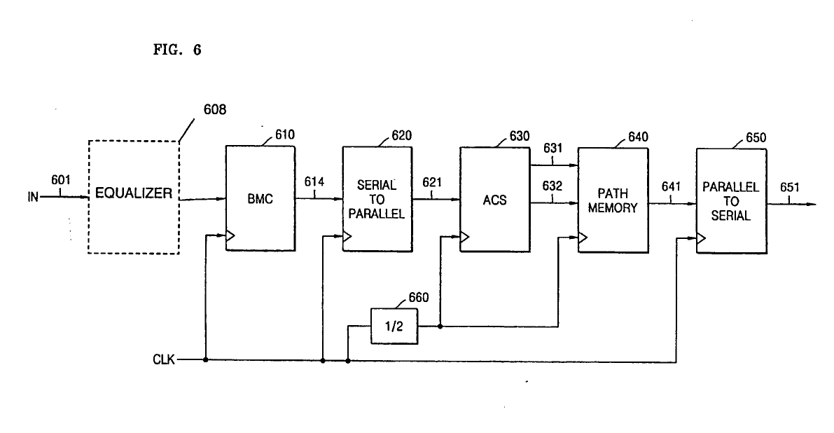

FIG. 5 illustrates trellis diagrams before and after 1T paths are removed. The left and right diagrams in FIG. 5 are trellis diagrams before and after 1T paths are removed, respectively. As shown in FIG. 5, a total of two paths are removed.

In FIGS. 3, 4, and 5, a radix-2 structure is extended to a radix-4 structure, and two 1T paths are removed. If the radix-2 structure is extended to the radix-8, six paths may be removed. Furthermore, if the radix-2 structure is extended to the radix-16 structure, many more paths may be removed. This is based on the fact that, as radix numbers increase, a viewing angle for a code arrangement is widened. In other words, the longer a unit to cut an input code to remove 1T paths, the more 1T paths are detected.

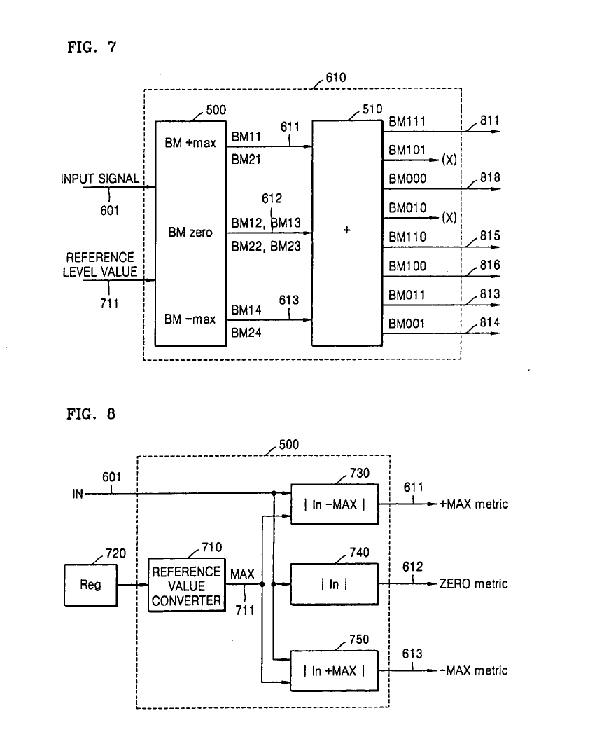

FIG. 6 is a view illustrating a construction of a Viterbi detection apparatus according to an embodiment of the present invention.

The Viterbi detection apparatus according to an embodiment of the present invention comprises a branch metric calculation unit (BMC) 610, a serial-to-parallel conversion unit 620, an addition comparison selection unit (ACS) 630, a path memory (also referred to as a path metric memory) 640, a parallel-to-serial conversion unit 650, and a frequency divider 660. An input signal 601 may be input into the BMC 610, or if desired, may be input into an equalizer 608 coupled upstream from the BMC 610 to equalize the input signal 601 prior to branch metric calculations.

According to an embodiment of the present invention, the addition comparison selection unit 630 and the path metric memory 640 are operated based on a frequency divided by the frequency divider 660. Accordingly, a serial-to-parallel conversion unit 620 is disposed in front of the addition comparison selection unit 630, and a parallel-to-serial conversion unit 650 is disposed behind the path memory 641. If a structure of the Viterbi detection apparatus is extended to a radix-4 structure and its frequency is divided by 2, an output signal 621 of the serial-to-parallel conversion unit 620 is a 2-bit signal, and an output signal 641 of the path memory 640 is also a 2-bit signal. Similarly, output signals 621 and 641 are 3-bit signals and 4-bit signals in the case of in the radix-8 and radix-16 structures, respectively.

FIG. 7 is a view illustrating a construction of a branch metric calculation unit according to an embodiment of the present invention. The branch metric calculation unit 610 comprises an absolute value calculation unit 500 and an addition unit 510.

FIG. 8 is a view illustrating an internal construction of the absolute value calculation unit 500. The branch metric calculation unit 610 calculates each branch metric of the trellis diagram based on the input signal 601. The branch metric is defined as a Euclidean distance between the input signal 601 and a reference level value, and in general, may be obtained by calculating an absolute value of the input signal 601 subtracted by the reference level value. The branch metric calculation unit 610 may be commonly used, irrespective of a radix structure of the Viterbi detection apparatus. The branch metric calculation unit 610 is operated by using the same clock signal as the main clock signal, without dividing a frequency of a channel clock signal.

The condition of an equalizer of the embodiment is PR (a, b). Therefore, available reference level values are three values of +max, zero, and −max. Under the condition, the branch metric calculation unit 610 performs the following calculation.

If the condition of the equalizer is PR (1, 1) and input RF signals of the equalizer are 1.1, 1.3, −1.1, −1.2, +1.2, . . . , the input signals 601 of the branch metric calculation unit 610 are 2.4, 0.2, −2.3, 0.0, . . . . If the reference level values of +max, −max and zero are set at 2.0, 0, and −2.0, respectively, the +max branch metrics 611 are output as |2.4−2.0|=0.4, |0.2−2.0|=1.8, |−2.3−2.0|=4.3, . . . , the zero branch metrics 612 are output as |2.4−0.0|=2.4, |0.2−0.0|=0.2, |−2.3−0.0|=2.3, . . . , and the -max branch metrics 613 are output as |2.4+2.01=4.4, |0.2+2.01=2.2, |−2.3+2.01=0.3, . . . .

The values of the branch metrics of FIG. 7 are obtained by matching the branch metrics to the branches of the trellis diagram of FIG. 3, as follows:
first radix +max/+1 branch metric BM11=0.4,
first radix zero/−1 branch metric BM12=2.4,
first radix zero/+1 branch metric BM13=2.4,
first radix −max/−1 branch metric BM14=4.4.
second radix +max/+1 branch metric BM21=1.8,
second radix zero/−1 branch metric BM22=0.2
second radix zero/+1 branch metric BM23=0.2, and
second radix −max/−1 branch metric BM24=2.2.

Returning to FIG. 8, since the branch metrics BM11 to BM14 and BM21 to BM24, as outputs of the absolute value calculation unit 500 represent only the branch metric values in the extended radix-4 structure, the path branch metrics corresponding to the paths must be obtained to obtain the state metrics of the next state. The path branch metric is defined by using path metric branch values of the paths which are available in a single state change. In other words, the path branch metric is a sum of branch metrics of branches in a single path defined based on a change of states. For example, paths having states changing from +1 to +1 include two available paths +1→+1→+1 and +1→−1→+1 and the respective path branch metrics are BM111 and BM101.

In a radix-4 structure, each of path branch metrics has two available paths based on a change of states. In the case of a change of states from +1 to +1, the paths +1→+1 include paths in which “+max +max” and “zero zero” are input at the current state +1. The respective path branch metrics are BM111 (=BM11+BM21) and BM101 (=BM12+BM23). All the path branch metrics are obtained with the similar method, as follows:
Case: +1→+1
BM111=BM11+BM21 - - - (1)
BM101=BM12+BM23 - - - (2) Removable
Case: −1→−1
BM000=BM14+BM24 - - - (3)
BM010=BM13+BM21 - - - (4) Removable
Case: +1→−1
BM110=BM11+BM22 - - - (5)
BM100=BM12+BM24 - - - (6)
Case: −1→+1
BM011=BM13+BM21 - - - (7)
BM001=BM14+BM23 - - - (8)

Paths having the path branch metrics BM101 and BM010 may be removed based on the code condition. Therefore, the branch metric calculation unit 610 need not have hardware for operations (2) and (4).

The absolute value calculation unit 500 generates branch metrics BM11 to BM14 and BM21 to BM24 by using the input signal 601 and the reference level value 711. The addition unit 510 calculates path branch metrics BM000 to BM111 (except BM101 and BM010) based on s change of the states by using the branch metrics BM11 to BM14 and BM21 to BM24 generated by the absolute value calculation unit 500. The calculation of the path branch metrics is carried out by extracting two available branch metrics among the branch metrics BM11 to BM14 and BM21 to BM24 based on a change of states and adding the two extracted branch metrics. In the present invention, the addition unit 520 does not generate the path branch metric of the path which is out of accord with the code condition.

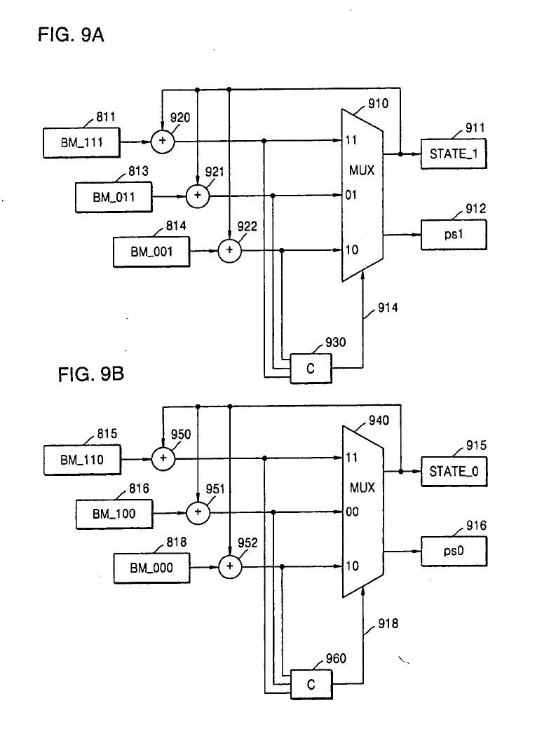

FIGS. 9A-9B illustrate structural views of an addition comparison selection unit 630 according to an embodiment of the present invention. FIGS. 9A-9B illustrate addition, comparison, and selection operations on the state metrics for all the paths going into the states +1 and −1, respectively. In the two views, the paths which are out of accord with the code condition are removed.

First, referring to the upper view of FIG. 9, the path branch metrics 811, 813, and 814 calculated in the branch metric calculation unit 610 are added to the previous state metric 911 by the adders 920, 921, and 922. The path branch metrics 811, 813, and 814 correspond to the paths going into states next to the state +1. The comparator 930 receives and compares the added state metrics to select the path branch metric having a smallest state metric, and outputs a retaining path selection signal 914 to specify the selected state metric. The state metric corresponding to the selected path is stored as a new state metric 911.

The selection unit 910 selects three state metrics which are input based on the retaining path selection signal 914 and outputs the path selection signal 912 corresponding to the selected retaining path. In FIG. 9, the path selection signal 912 includes signals 11, 01, and 10. The signals 11, 01, and 01 correspond to cases wherein the path branch metrics BM111, BM011, and BM001 are selected, respectively. In the present invention, there is no signal meaning that the path branch metric BM101 is selected

The lower view of FIG. 9 illustrates a procedure of generating the path selection signal 916 by performing calculation, comparison, and selection operations on the state metrics of all the paths going into the state −1. All the operations are the same as those of the procedure for all the paths going into the state +1. In this case, the path selection signal 916 includes the signals 11, 00, and 10. In the embodiment, since the equalizer condition is PR (a, b), the corresponding state includes two states, +1 and −1. Accordingly, there are two path selection signals, including the first and second path selection signals 912 and 916.

The output signals 912 and 916 of the addition comparison selection unit shown in FIG. 9 have two bits because the radix structure of the Viterbi detection apparatus is extended from the radix-2 structure to the radix-4 structure to process multiple bits.

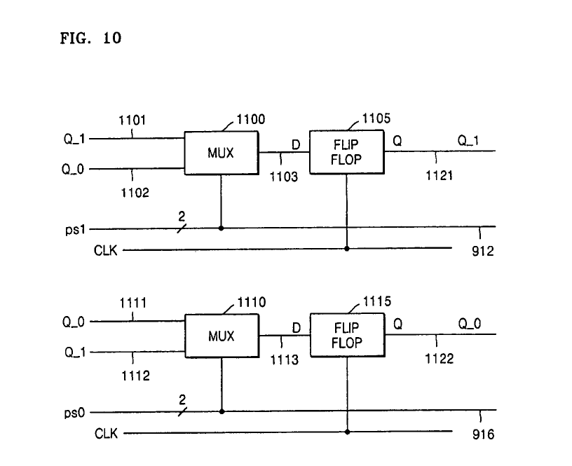

FIG. 10 is a view illustrating a path memory 640 according to an embodiment of the present invention. In the embodiment, the path memory 640 is constructed in a register exchange manner in accordance with the trellis diagram of FIG. 3, similar to the addition comparison selection unit 630. A first selector 1100 receives a first path selection signal 912 from the addition comparison selection unit 630 and selects one out of the register values 1101 and 1102 of the path memory with reference to the first path selection signal 912 to generate a path selection signal 1103. At this time, the path selection signal 1103 is stored as the two lowest bits values Q_{—}1 and Q_{—}0 of the state registers using a first flip-flop 1105. Existing values are shifted by two bits toward the highest bit. The shifted existing values become output signals 1121 of the path memory 640.

Operations of a second selector 1110 and a flip-flop 1115 are the same as those of the first selector 1100 and 1105 except that they are driven by a second path selection signal 916. In another embodiment, if a structure of the Viterbi detection apparatus is extended to a radix-8 structure, the path selection signal has three bits, and the values of the state registers are shifted by 3 bits.

Output signals 1121 and 1122 of the path memory 630 are output bit by bit at a channel clock speed, that is, a main clock speed in the parallel-to-serial conversion unit 650. A final output signal 651 of the Viterbi detection apparatus is obtained by using the output signals 1121 and 1122.

According to an embodiment of the present invention, paths containing 1T code based on a code condition even under a condition PR (a, b) are removed by extending a radix structure to facilitate high speed operation.

Although a few embodiments of the present invention have been shown and described, it would be appreciated by those skilled in the art that changes may be made in these embodiments without departing from the principles and spirit of the invention, the scope of which is defined in the claims and their equivalents.

1. A Viterbi detection apparatus comprising:
a branch metric calculation unit;
an addition comparison selection unit, downstream from the branch metric calculation unit; and
a path memory downstream from the addition comparison selection unit,
wherein multiple bits are processed during a single operational clock cycle by using an auxiliary clock signal having 1/n of a frequency of a main clock signal, wherein n is a natural number greater than or equal to 2, and wherein a path of a signal has a shorter cycle than an input code which is not detected in a case of operating based on an existing clock signal.

2. The Viterbi detection apparatus according to claim 1, wherein an operational speed is increased by extending a structure of the Viterbi decoding apparatus from radix-2 to a structure of at least radix-4.

3. A Viterbi detection apparatus having a branch metric calculation unit, an addition comparison selection unit downstream from the branch metric calculation unit, and a path memory downstream from the addition comparison selection unit, the apparatus further comprising:
a frequency divider, downstream from the addition comparison selection unit and the path memory, to divide a frequency of a main clock signal by n, wherein n is a natural number greater than or equal to 2, to generate an auxiliary clock signal;
a serial-to-parallel conversion unit, downstream from the branch metric calculation unit, to output branch metrics in n state units to the addition comparison selection unit, wherein the branch metrics are calculated based on the main clock signal; and
a parallel-to-serial conversion unit, downstream from the path memory, to convert output data of the path memory to serial data based on the auxiliary clock signal,
wherein a path of a signal which is out of accord with a code condition in a case of operating based on an existing clock signal is removed from paths selected by the addition comparison selection unit.

4. The Viterbi detection apparatus according to claim 3, wherein the Viterbi detection apparatus further comprises an equalizer coupled upstream from the branch metric calculation unit to equalize an input signal, and an output condition of the equalizer is PR (a, b).

5. The Viterbi detection apparatus according to claim 4, wherein a 1T condition path is removed when the code condition is (1, M).

6. The Viterbi detection apparatus according to claim 5, wherein the Viterbi detection apparatus is constructed in a radix-4 structure, n equals 2, and two bits are simultaneously processed.

7. The Viterbi detection apparatus according to claim 5, wherein the Viterbi detection apparatus is constructed in a radix-8 structure, n equals 3, and three bits are simultaneously processed.

8. The Viterbi detection apparatus according to claim 3, wherein the Viterbi detection apparatus is constructed in a radix-16 structure, n equals 4, and four bits are simultaneously processed.

9. A Viterbi detection apparatus, comprising:
a branch metric calculation unit to calculate branch metrics;
an addition comparison selection unit to calculate state metrics based on the branch metrics, compare the state metrics, select a path having a smallest value among the state metrics, and generate a path selection signal; and
a path memory unit to output data corresponding to the path selection signal,
wherein a state metric calculation is not performed on paths which are out of accord with a code condition when a structure of the Viterbi decoding apparatus is extended from radix-2 to a structure of at least radix-4.

10. The Viterbi detection apparatus according to claim 9, wherein the apparatus further comprises:
a frequency divider to generate an auxiliary clock signal having a frequency obtained by dividing a frequency of a main clock signal by n, wherein n is a natural number greater than or equal to 2;
a serial-to-parallel conversion unit to output branch metrics in n state units,
wherein the branch metrics are calculated in the branch metric calculation unit based on the main clock signal; and
a parallel-to-serial conversion unit to store the path selection signal based on the auxiliary clock signal and output data corresponding to the path selection signal in parallel.

11. The Viterbi detection apparatus according to claim 10, wherein the apparatus further comprises an equalizer coupled upstream from the branch metric calculation unit to equalize an input signal, and an output condition of the equalizer is PR (a, b).

12. The Viterbi detection apparatus according to claim 11, wherein a 1T condition path is removed when the code condition is (1, M).

13. The Viterbi detection apparatus according to claim 12, wherein the branch metric calculation unit comprises:
an absolute value operation unit to calculate the branch metric of each branch by performing an absolute value operation on a difference between a reference level value and an input signal; and
an addition unit to calculate a path branch metric by selecting and adding the calculated branch metrics based on corresponding states.

14. The Viterbi detection apparatus according to claim 13, wherein, in the addition unit, the path metric calculation is not performed on paths which are out of accord with a code condition among paths available to the corresponding states.

15. The Viterbi detection apparatus according to claim 14, wherein the Viterbi detection apparatus is constructed in a radix-4 structure, n equals 2, and two bits are simultaneously processed.

16. The Viterbi detection apparatus according to claim 15, wherein the code condition is (1, M), and the path metric calculation is not performed on paths corresponding to the state +1 −1 +1 or −1 +1 −1.

17. The Viterbi detection apparatus according to claim 14, wherein the Viterbi detection apparatus is constructed in a radix-8 structure, n equals 3, and three bits are simultaneously processed.

18. The Viterbi detection apparatus according to claim 14, wherein the Viterbi detection apparatus is constructed in a radix-16 structure, n equals 4, and four bits are simultaneously processed.

19. A Viterbi detection method, comprising:
calculating branch metrics;
calculating state metrics based on the branch metrics, comparing the state metrics, selecting a path having a smallest value among the state metrics, and generating a path selection signal; and
outputting data corresponding to the path selection signal,
wherein a state metric calculation is not performed on paths which are out of accord with a code condition when a structure of Viterbi decoding apparatus is extended from radix-2 to a structure of at least radix-4.

20. The Viterbi detection method according to claim 19, wherein the method further comprises:
generating an auxiliary clock signal having a frequency obtained by dividing a frequency of a main clock signal by n, wherein n is a natural number greater than or equal to 2;
outputting branch metrics in n state units, wherein the branch metrics are calculated based on the main clock signal used in calculating the branch metrics; and
storing the path selection signal based on the auxiliary clock signal and outputting data corresponding to the path selection signal in parallel.

21. The Viterbi detection method according to claim 20, further comprising equalizing an input RF signal, wherein an output condition of the equalizing is PR (a, b).

22. The Viterbi detection method according to claim 21, wherein a 1T condition path is removed when the code condition is (1, M).

23. The Viterbi detection method according to claim 22, wherein the calculating branch metrics comprises:
calculating a branch metric of each branch by performing an absolute value operation on a difference between a reference level value and an input signal; and
calculating path branch metrics by selecting and adding the calculated branch metrics based on the corresponding states.

24. The Viterbi detection method according to claim 23, wherein, in the calculating path branch metrics by selecting and adding the calculated branch metrics based on the corresponding states, the path metric calculation is not performed on paths which are out of accord with a code condition among paths available to the corresponding states.

25. The Viterbi detection method according to claim 24, wherein the Viterbi detection method is constructed in a radix-4 structure, n equals 2, and two bits are simultaneously processed in:
the calculating state metrics based on the branch metrics, comparing the state metrics, selecting a path having a smallest value among the state metrics, and generating a path selection signal; and
the outputting data corresponding to the path selection signal.

26. The Viterbi detection method according to claim 25, wherein the code condition is (1, M), and the path metric calculation in the calculating branch metrics is not performed on paths corresponding to a state +1 −1 +1 or −1 +1−61.

27. The Viterbi detection method according to claim 24, wherein the Viterbi detection method is constructed in a radix-8 structure, n equals 3, and three bits are simultaneously processed in:
the calculating state metrics based on the branch metrics, comparing the state metrics, selecting a path having a smallest value among the state metrics, and generating a path selection signal; and
the outputting data corresponding to the path selection signal.

28. The Viterbi detection method according to claim 24, wherein the Viterbi detection method is constructed in a radix-16 structure, n equals 4, and four bits are simultaneously processed in:
the calculating state metrics based on the branch metrics, comparing the state metrics, selecting a path having a smallest value among the state metrics, and generating a path selection signal; and
the outputting data corresponding to the path selection signal.

29. A computer-readable recording medium having stored thereon a computer program that performs a Viterbi detection method by:
calculating branch metrics;
calculating state metrics based on the branch metrics, comparing the state metrics, selecting a path having a smallest value among the state metrics, and generating a path selection signal; and
outputting data corresponding to the path selection signal,
wherein a state metric calculation is not performed on paths which are out of accord with a code condition when a structure of Viterbi decoding apparatus is extended from radix-2 to a structure of at least radix-4.
